(19) United States
(12) Patent Application Publication
(10) Pub. No.: US 2024/0174832 A1
(43) Pub. Date: May 30, 2024

(54) METHOD FOR PREPARING HIGHLY STRETCHABLE CIP/PDMS COMPOSITE, HIGHLY STRETCHABLE CIP/PDMS COMPOSITE PREPARED THEREBY, AND HIGHLY STRETCHABLE EM NOISE SUPPRESSOR INCLUDING THE SAME

(71) Applicant: Chungang University Industry Academic Cooperation Foundation, Seoul (KR)

(72) Inventor: Byungil HWANG, Seoul (KR)

(73) Assignee: Chungang University Industry Academic Cooperation Foundation, Seoul (KR)

(21) Appl. No.: 18/517,719

(22) Filed: Nov. 22, 2023

(30) Foreign Application Priority Data
Nov. 22, 2022 (KR) 10-2022-0157121

(51) Int. Cl. C08K 3/18

(52) U.S. Cl. CPC C08K 3/18; C08K 2201/019

(57) ABSTRACT

Disclosed are a method for preparing a highly stretchable CIP/PDMS composite, a highly stretchable CIP/PDMS composite prepared thereby, and a highly stretchable electromagnetic (EM) noise suppressor including the same. The method for preparing the highly stretchable CIP/PDMS composite includes a first step of adding and mixing CIPs (Carbonyl Iron Powders) to and with a PDMS (Polydimethylsiloxane) solution to produce a first mixed solution; a second step of adding and mixing a curing agent to and with the first mixed solution to produce a second mixed solution; and a third step of transferring the second mixed solution into a mold and then curing the second mixed solution in the mold.

### CROSS-REFERENCE TO RELATED APPLICATIONS

This application claims the benefit under 35 USC § 119(a) of Korean Patent Application No. 10-2022-0157121 filed on Nov. 22, 2022 in the Korean Intellectual Property Office, the entire disclosure of which is incorporated herein by reference for all purposes.

### BACKGROUND

### 1. Field

The present disclosure relates to a method for preparing a highly stretchable CIP/PDMS composite, a highly stretchable CIP/PDMS composite prepared thereby, and a highly stretchable electromagnetic (EM) noise suppressor including the same, and, and more specifically, to a composite of PDMS and CIP from which a surface oxide film has been removed.

### 2. Description of Related Art

Electromagnetic (EM) radiation emitted from wearable electronic devices operating in the gigahertz (GHz) bandwidth may cause the devices to malfunction or pose a risk to human health. Attempts to integrate and miniaturize electronic devices are increasing the risk due to EM (Electromagnetic) noise. Therefore, various types of materials, including micro-metal mesh and polymer-based composite materials, are being actively developed for EM noise suppressors. Among them, composite materials including a polymer matrix and magnetic/conductive fillers are the most popular for wearable electronic products due to their light weight, adjustable elasticity, and formability.

Since the EM noise suppression performance of the composite materials greatly depends on the magnetic and electrical properties of the filler, MXene, GaN, conductive polymer composite (CPC), ferrite-based alloy powder, and carbonyl iron powder (CIP) together with the development of filler materials including carbon-based materials are being studied. Although the carbon-based materials and MXene exhibit efficient noise suppression over a wide wavelength region, CIP becomes the most commercially available filler because it may be produced inexpensively in large quantities using thermal decomposition and exhibits high saturation magnetization and permeability in the GHx band.

Stretchability is a desirable property for wearable electronics materials. A large amount of filler may be added to CIP composite materials such that high EM noise suppression efficiency is achieved by. However, this reduces the stretchability of the composite material. In previous studies, 40 vol % CIP/PDMS composite exhibits 2.25 times higher EM noise suppression efficiency than that of 20 vol % CIP/PDMS composite. However, as the vol % of CIP increased, the failure strain decreased from about 145% to 71%. Because the wearer's movement causes more than 75% deformation in the wearable device, the stretchability of composite materials should be improved. Furthermore, the quality of the product should be twice that of the general use industry standard. This is a method to dramatically improve the stretchability of composite materials without weakening the EM noise suppression effect as a classic but unresolved problem in this field.

Although no demonstration of EM noise suppression has been performed, there is a lot of research on stretchability conductors that exhibit excellent stretchability. For example, thermoplastic polyurethane (PU)/carbon nanotube (CNT) composite, which exhibits a high stretchability of about 250% is effective in terms of structural design and in increasing stretchability. Furthermore, 100% stretchability was achieved through a kirigami structure composed of MXene and PDMS composite. Further, the honeycomb structure using copper micro coil/rubber composite material exhibited 100% stretchability.

From a similar perspective, there are EM noise suppressors with improved stretchability and high EMI absorption performance. For example, 3D structured composite materials for EM noise suppression are known. In this regard, PU foam with 3D structural backbone is coated with 4.6 vol % CNTs and then mixed with ecoflex. The 3D composite material exhibits high stretchability of 150% and EMI shielding efficiency of 30 dB, but its relatively large thickness of 3 mm makes it difficult for the same to be used in future small devices. A composite thin-film composed of graphene oxide and PDMS as fabricated using a 3D printing method had an appropriate stretchability of 130%, but the EMI shielding efficiency thereof was relatively low at 25 dB at 10 GHz. The wavy structure composite composed of MXene and thermoplastic PU nanofibers exhibited a high EMI shielding efficiency of 30 dB, but stretchability thereof was relatively low at 70%. Despite the high stretchability and excellent electromagnetic wave absorption performance of the composites in existing research, methods for preparing composite materials using structural engineering or expensive nanomaterials were somewhat complicated, thereby increasing production costs. Therefore, there is a need to develop composite materials that may be prepared in a cost-effective manner while simultaneously achieving a small thickness, high stretchability, and excellent EM absorption performance in the X-band region.

### SUMMARY

A purpose of the present disclosure is to provide a method for preparing a highly stretchable CIP/PDMS composite.

Another purpose of the present disclosure is to provide a highly stretchable EM noise suppressor including the highly stretchable CIP/PDMS composite.

Still another purpose of the present disclosure is to provide the highly stretchable CIP/PDMS composite prepared using the above method.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

A first aspect of the present disclosure provides a method for preparing a highly stretchable CIP/PDMS composite for a highly stretchable EM noise suppressor, the method comprising: a first step of adding and mixing CIPs (Carbonyl Iron Powders) to and with a PDMS (Polydimethylsiloxane) solution to produce a first mixed solution; a second step of adding and mixing a curing agent to and with the first mixed solution to produce a second mixed solution; and a third step of transferring the second mixed solution into a mold and then curing the second mixed solution in the mold.

According to some embodiments of the method, each of the CIPs is free of a surface oxide film.

According to some embodiments of the method, the surface oxide film is made of silicon oxide (SiO₂).

According to some embodiments of the method, the surface oxide film has been removed from each of the CIPs by sequentially washing the CIPs using 0.5 M hydrochloric acid (HCl), distilled water, ethanol, and acetone.

According to some embodiments of the method, the CIPs from which the surface oxide film has been removed is added to the first mixed solution at a content of 40 vol % or smaller based on a total volume of the first mixed solution.

According to some embodiments of the method, in a mixture of the CIPs and the PDMS, a free space is defined around the CIP.

According to some embodiments of the method, the mixing of each of the first step and the second step is carried out using a revolving and rotating mixer.

According to some embodiments of the method, the curing includes thermal curing, wherein a thermal curing temperature is in a range of 80 to 120° C.

A second aspect of the present disclosure provides a highly stretchable CIP/PDMS composite prepared by the method as described above.

According to some embodiments of the highly stretchable CIP/PDMS composite, each of the CIPs is free of a surface oxide film.

According to some embodiments of the highly stretchable CIP/PDMS composite, the surface oxide film is made of silicon oxide (SiO₂).

According to some embodiments of the highly stretchable CIP/PDMS composite, the CIP/PDMS composite has a stretchability of about 165% or greater.

According to some embodiments of the highly stretchable CIP/PDMS composite, the CIP/PDMS composite removes electromagnetic (EM) noise.

A third aspect of the present disclosure provides a highly stretchable EM noise suppressor including the highly stretchable CIP/PDMS composite as described above.

According to the present disclosure, the surface of CIP may be modified so as to have weak partial interface bonding with the PDMS. Thus, the CIP/PDMS matrix composite including the surface-modified CIP may exhibit ultra-high stretchability of about 168% even at a high filler content of about 40 vol %, and may exhibit excellent EM noise suppression performance.

Furthermore, the CIP/PDMS matrix composite including the surface-modified CIP in accordance with the present disclosure may overcome the trade-off between the EM noise suppression and the stretchability for next-generation wearable electronics that require large-scale data communication and are subjected to severe deformation.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a schematic diagram of a preparing process of the present disclosure.

FIG. 2A shows SEM images of cross-sections of CIP-FID (Full Interface Bonding) and FIG. 2B shows CIP-PID (Partial Interface Bonding) (an inset is an EDS line scan graph related to Si) and FIG. 2C shows SEM images of plan views of CIP-FID/PDMS composite and FIG. 2D shows CIP-PID/PDMS composite.

FIG. 3 is the XRD pattern graph of CIP-FID and CIP-PID.

FIG. 4A to 4D are XPS graphs related to FIG. 4A CIP-FID, FIG. 4B CIP-PID, FIG. 4C O1s peak of CIP-FID, and FIG. 4D O1s peak of CIP-FID (an inset relates to Si2p peak).

FIG. 5A and 5B are OM (optical microscopy) images measuring the contact angle of the particle surface with respect to water of each of FIG. 5A CIP-FID and FIG. 5B CIP-PID.

FIG. 6A shows the Gibbs free wetting enthalpy (ΔG) based on the CIP surface or the polymer matrix, FIG. 6B shows the OM image of CIP-FID, FIG. 6C shows the OM image of CIP-PID, FIG. 6D shows the OM of CIP-TEOS, and FIG. 6E shows the OM image of CIP-APTES/PDMS composite (an inset is a plan view of the SEM image).

FIG. 7A is a SEM photograph of the composite after applying tensile stress thereto when the SiO₂ oxide film is removed from CIP and FIG. 7B is a SEM photograph of the composite after applying tensile stress thereto when the SiO₂ oxide film is not removed from CIP.

FIG. 8A shows the tensile test results based on CIP content when the SiO₂ oxide film is not removed from CIP, FIG. 8B shows the tensile test results based on CIP content when the SiO₂ oxide film is removed therefrom, and FIG. 8C shows the tensile test results based on CIP content in case of CIP composite using various polymer matrices.

FIG. 9A to 9D show the numerically calculated displacement at a tensile load of 100 kPa of each of FIG. 9A CIP-FID based PDMS composite and FIG. 9B CIP-PID based PDMS composite, and the stress component calculated below 100 kPa of each of FIG. 9C CIP-FID based PDMS composite and FIG. 9D CIP-PID based PDMS composite.

FIG. 10A and 10B show a real part and an imaginary part of the permeability of CIP/PDMS composite in the frequency range of 1 to 18 GHZ, and FIG. 10C and 10D show magnetic loss tangent and power loss of the CIP/PDMS composite in the frequency range of 1 to 18 GHz.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

The features of the various embodiments of the present disclosure may be partially or entirely combined with each other and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas but should be understood as examples of the terms for describing embodiments.

A first aspect of the present disclosure provides a method for preparing a highly stretchable CIP/PDMS composite for a highly stretchable EM noise suppressor, the method comprising: a first step of adding and mixing CIPs (Carbonyl Iron Powders) to and with a PDMS (Polydimethylsiloxane) solution to produce a first mixed solution; a second step of adding and mixing a curing agent to and with the first mixed solution to produce a second mixed solution; and a third step of transferring the second mixed solution into a mold and then curing the second mixed solution in the mold.

As the amount of data communication increases with the development of 5G communication, failures/malfunctions of electronic devices due to electromagnetic noise interference are becoming a problem. Therefore, an appropriate EM noise suppressor is needed. In particular, the increase in wearable/stretchability devices requires manufacturing of stretchability EM noise suppressors. However, there are still not many examples of simultaneously securing stretchability and EM noise reduction effects.

Therefore, in accordance with the present disclosure, a composite for the EM noise suppressor is prepared by mixing iron carbide powders (CIPs) as magnetic particles and PDMS as a stretchability material with each other, and in particular, highly stretchability is secured via control of the surface oxide film of the CIP.

The CIP may be free of a surface oxide film. The surface oxide film may be made of silicon oxide (SiO₂). The surface oxide film may be removed from the CIP by sequentially washing the CIP using 0.5 M hydrochloric acid (HCl), distilled water, ethanol, and acetone.

Partial interface bonding may be achieved between the CIP from which the surface oxide film has been removed and the PDMS matrix. In general CIP/PDMS composite, the applied strain is limited to the CIP/PDMS interface. Increasing the CIP content to improve EM noise suppression increases the strain localization ratio at the particle-matrix interface, which reduces the stretchability of the composite. To alleviate the strain localization, CIP may be modified such that the partial interface bonding between CIP and PDMS may be achieved. The partial interface bonding of CIP with the PDMS may result in a weak and incomplete bonding, thereby allowing the PDMS matrix to stretch without cracking due to stress localization. The stretchability of the CIP/PDMS composite with the partial interface bonding therebetween may be two times higher than that of general CIP/PDMS composite having full interface bonding therebetween.

The CIP from which the surface oxide film has been removed may be added at 40 vol % based on a total volume of the first mixed solution.

In the mixture of the CIP and the PDMS, the free space may be defined around the CIP.

When the PDMS is missed with the CIP from which the surface oxide film has been removed, the free space may be defined around the CIP. In general, the surface oxide film of CIP has high wettability with PDMS to generate a strong bonding force thereto. Thus, removing the surface oxide film therefrom may allow the wettability to be reduced such that the bonding force may be adjusted to a low level. In this way, the free space may be generated. Thus, when the composite is pulled, the free space may increase such that the cracks may be prevented from occurring in the composite. When the CIP from which the surface oxide film has been removed is added at 40 vol % based on a total volume of the first mixed solution, a finally prepared composite sample exhibits the stretchability that is increased by 3 times or greater. However, there is no difference in the EM noise reduction effect depending on whether the surface oxide film has been removed therefrom. Thus, according to the present disclosure, the EM noise reduction effect and the high stretchability may be secured at the same time.

The mixing of each of the first step and the second step may be performed using a revolving and rotating mixer. Specifically, the surface-modified CIP and the PDMS may be mixed with each other using the revolving and rotating mixer and then the mixture may be subjected to a thermal curing process. In this regard, the thermal curing temperature may be in a range of 80 to 120° C.

A second aspect of the present disclosure provides a highly stretchable CIP/PDMS composite for a highly stretchable EM noise suppressor prepared by the method for preparing the highly stretchable CIP/PDMS composite for the highly stretchable EM noise suppressor as described above.

In the CIP/PDMS composite, the surface oxide film has been removed from the CIP.

The surface oxide film may be made of silicon oxide (SiO₂).

The CIP/PDMS composite may have a stretchability of about 168%.

The CIP/PDMS composite may remove electromagnetic (EM) noise.

A third aspect of the present disclosure provides a highly stretchable EM noise suppressor including the highly stretchable CIP/PDMS composite as prepared by the method for preparing the highly stretchable CIP/PDMS composite for the highly stretchable EM noise suppressor as described above.

Hereinafter, the partial interface bonding of CIP with PDMS improving the stretchability of the composite will be described along with specific Examples. However, the examples as described below are only some embodiments of the present disclosure, and the scope of the present disclosure is not limited to the examples below.

### Example: CIP/PDMS Composite Preparing Method

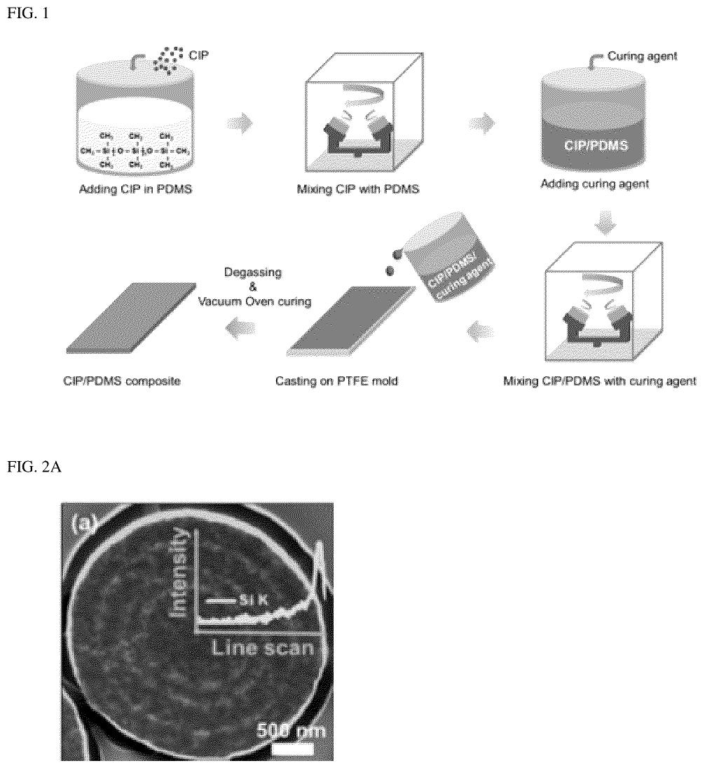

FIG. 1 is a schematic diagram of a preparing process of the present disclosure.

Referring to FIG. 1, first, PDMS (polydimethylsiloxane) and CIPs were mixed with each other at 2,000 rpm in vacuum at 20 kPa for 5 minutes without a curing agent.

In this regard, CIP was free of the oxide film (SiO₂) on the surface thereof. The CIP from which the surface oxide film was removed was prepared as follows.

CIPs together with a magnet were poured into a beaker. In this regard, the magnet accelerates particle deposition. Next, the CIPs were sequentially washed using 0.5 M HCl, distilled water, ethanol, and acetone.

Next, a curing agent was added to the mixed solution which in turn was stirred at 1.200 rpm, 80 kPa, for 3 minutes.

Then, the CIP/PDMS mixture was input into a casting mold made of PTFE (polytetrafluoroethylene) and having a dimension of each of 40(w)×30(l)×0.3 mm(t) and 8(w)×48(l)×0.3 mm(t). To remove air bubbles from the CIP/PDMS mixture, the mixture was degassed in a vacuum oven at 15 kPa for 3 hours.

The prepared mixture was stored in a vacuum oven at 100° C. for 2 hours.

### Experimental Example 1: Characterization of CIP Based on FID and PID

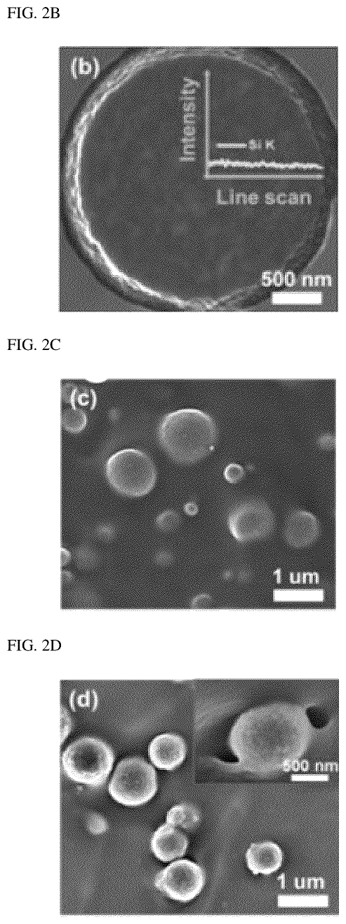

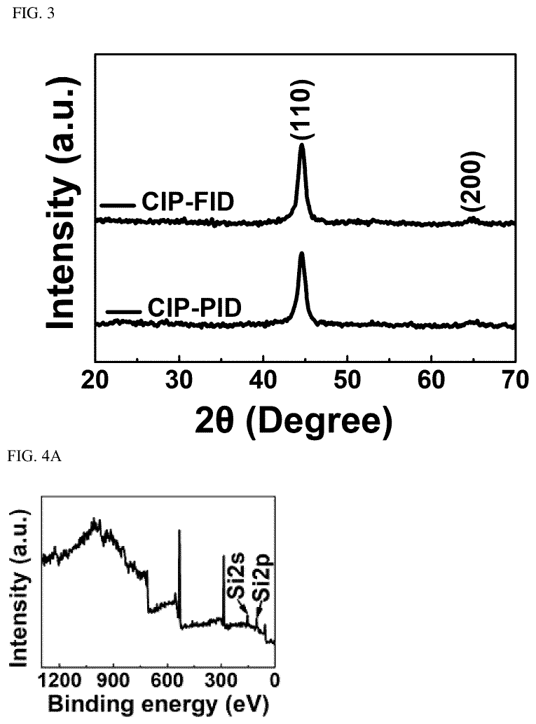

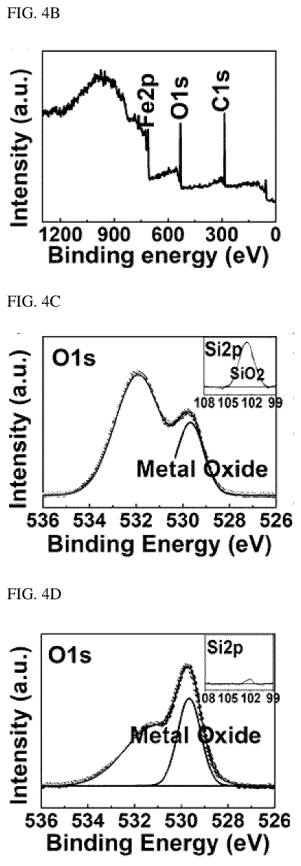

FIG. 2A shows SEM images of cross-sections of CIP-FID (Full Interface Bonding) and FIG. 2B shows CIP-PID (Partial Interface Bonding) (an inset is an EDS line scan graph related to Si) and FIG. 2C shows SEM images of plan views of CIP-FID/PDMS composite and FIG. 2D shows CIP-PID/PDMS composite. FIG. 3 is the XRD pattern graph of CIP-FID and CIP-PID. FIG. 4A to 4D are XPS graphs related to FIG. 4A CIP-FID, FIG. 4B CIP-PID, FIG. 4C O1s peak of CIP-FID, and FIG. 4D O1s peak of CIP-FID (an inset relates to Si2p peak). FIG. 5A and 5B are OM (optical microscopy) images measuring the contact angle of the particle surface with respect to water of each of FIG. 5A CIP-FID and FIG. 5B CIP-PID.

Referring to FIG. 2A-2B, FIG. 3, FIG. 4A-4D, and FIG. 5A-5B, the CIP particle is spherical and has an average diameter of approximately 1.1 μm. As shown in the EDX line scan graph, the magnetic grade CIP used as a filler in the EM noise suppressor is covered with a SiO₂ insulating layer. This layer serves to reduce eddy current generation between adjacent CIP particles. The CIP has a strong chemical bond with PDMS [(CH₃)₂SiO]ₙ via the (Si—O—Si) covalent bond between —Si of the SiO₂ surface and —Si of the broken PDMS chain. The reaction is as shown in following Reaction Formula 1.

SIOH+(CH₃)₂OSi(CH₃)₂→SiOSi(CH₃)₃+(CH₃)₂OH [Reaction Formula 1]

Furthermore, the physical (O . . . H) bond generated by the interaction between the —OH group of the silicon surface and the —O— of the PDMS backbone contributes to the bonding of the CIP and PDMS matrix. Due to the strong adhesion generated by the covalent bonds together with the additional contribution of hydrogen bonds, the SiO₂ layer of the CIP does not form a free surface at the interface with the PDMS matrix, resulting in strong and full interface bonding. To generate partial interface bonding between the PDMS matrix and CIP, the SiO₂ layer was removed from the CIP surface.

Based on the cross-sectional SEM image of CIP without the SiO₂ layer that may generate CIP-PID in the PDMS/CIP composite, it was identified that the shape of the CIP without the SiO₂ layer was also spherical. Based on an identifying result of the EDX line scan graph, it was clearly visible that there was no SiO₂ layer on the surface of CIP. Si2s and Si2p peaks were observed in CIP and were not detected in CIP-PID. Furthermore, the CIP-PID/PDMS composite exhibited a less strong O₁ peak which was not the case in CIP-FID/PDMS composite. In O1 and Si2P spectra, CIP-FID consistently exhibited a SiO₂ peak at each of binding energies of 531.9 and 102.5 eV. However, CIP-PID did not exhibit a SiO₂ peak while exhibiting strong C═O bond at the carbonyl group of CIP. No other significant differences in the crystallographic structure between raw CIP and the CIP without SiO₂ are expected because the XRD results of the raw CIP and the CIP without SiO₂ exhibit a single Fe peak with similar full width half maximum (FWHM) values except for the presence of SiO₂ on the surface thereof. The raw CIP and the CIP without SiO₂ exhibit the same 20θ value of 44.6°.

Measurement of the particle surface contact angle with respect to water indicates that the surface of CIP-PID was more hydrophilic than the surface of CIP-FID was. This is because there are more -OH groups on the surface of CIP-PID than on the surface of CIP-FID. Therefore, a larger number of physical bonds are expected to be present on CIP-PID than on CIP-FID because a larger number of hydroxyl groups are present on the CIP-PID surface. However, the CIP-PID/PDMS composite mainly have weak hydrogen bonds and lacks strong covalent bonds. As a result, the partial interface bonding is generated between the CIP without the SiO₂ layer and the PDMS matrix, thereby forming a free surface at the interface between the CIP particle and the PDMS matrix.

The full interface bonding between the CIP and the PDMS is generated in a silica shell prepared by coating CIP-PID thereon via reaction with Si(OC₂H₅)₄(TEOS) or H₂N(CH₂)₃Si(OC₂H₅)₃(ATPES). Based on CIP-FID, it was identified that Si had the strong contribution to interface bonding. This observation indicates that the use of additives that improve adhesion between interfaces, such as Si or surfactant should be avoided to generate the partial interface bonding in the CIP/PDMS composite.

### Experimental Example 2: Dispersibility of Each of CIP-PID and CIP-FID

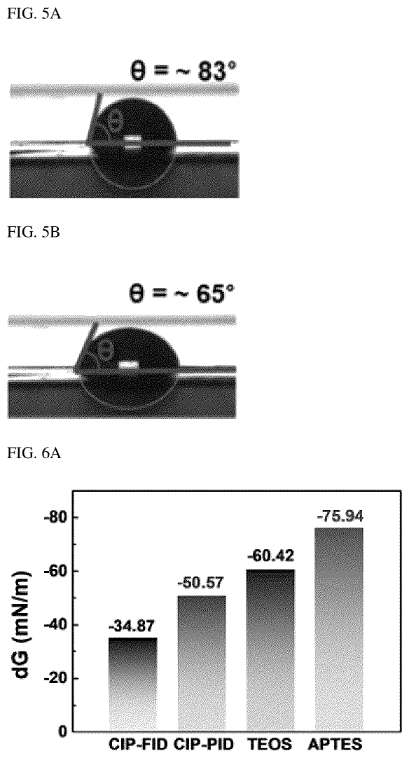

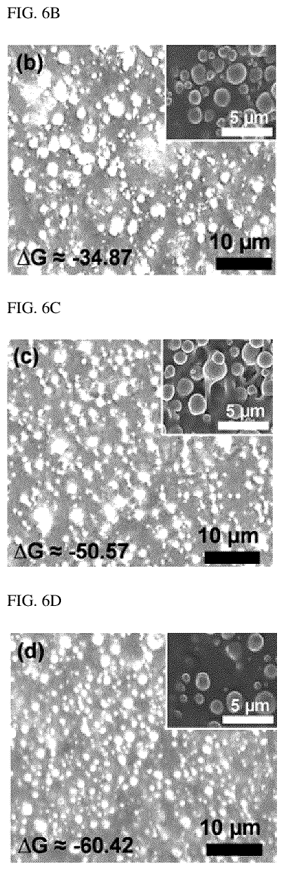

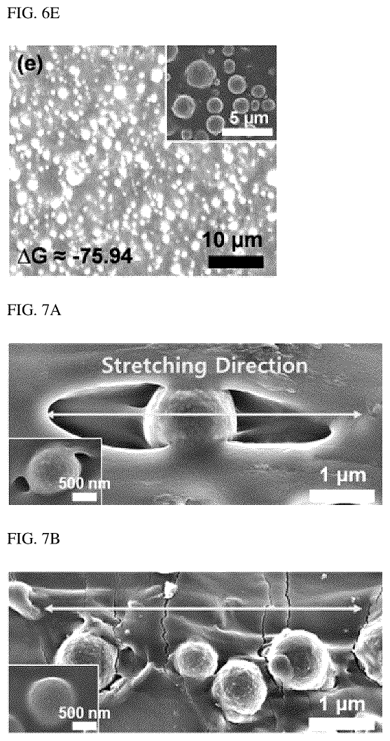

FIG. 6A shows the Gibbs free wetting enthalpy (ΔG) based on the CIP surface or the polymer matrix, FIG. 6B shows the OM image of CIP-FID, FIG. 6C shows the OM image of CIP-PID, FIG. 6D shows the OM of CIP-TEOS, and FIG. 6E shows the OM image of CIP-APTES/PDMS composite (an inset is a plan view of the SEM image).

Referring to FIG. 6A-6D, the effect of surface modification of CIP on the dispersion state thereof in the PDMS matrix may be identified. The dispersion state affects the mechanical and magnetic performance of the composite material. Therefore, changes in dispersibility based on surface characteristics were identified. Dispersion of powders in a liquid matrix proceeds in three stages: wetting the powder surface with the liquid, mixing the two components with each other by a mixer, and preventing agglomeration after initial dispersion. Due to the viscous nature of PDMS, the powders can be uniformly dispersed only when the powder are spontaneously wetted with the liquid matrix. The thermodynamic spontaneity about the wettability of the powders may be predicted by associating the surface polarities of the powder and the polymer matrix expressed as the Gibbs free wetting enthalpy (ΔG) with each other.

ΔG=γₗ−2(\sqrt{( γₛ^{D}·γₗ^{D})}+{square root over ((γₛ^{P}·γₗ^{P})}),

In this regard, γₗ is the surface tension of the liquid, γₗ^{D} is the non-polar fraction (dispersive fraction) of the liquid matrix, γₗ^{P} is the polar fraction of the surface free energy of the liquid matrix γₛ^{D} is the non-polar fraction (dispersive fraction) of the surface free energy of the solid powder, and γₛ^{P} is the polar fraction of the surface free energy of the solid powder. As ΔG which is calculated based on the surface tension of the liquid matrix and the surface free energy of the solid particle is smaller, the powder may be wetted with the polymer matrix more naturally. To calculate the ΔG, the surface polarity was evaluated using the contact angles thereof with polar and nonpolar droplets, that is, DI water and diiodomethane, respectively. The ΔG values of CIP with various surfaces as calculated using experimental parameters, surface energy, and polarity are listed in Table 1.

TABLE 1

| | Contact angle | | | | |
|---|---|---|---|---|---|
| | | Non-polar | Surface | Dispersive | Polar |
| | Polar | (Diiodo- | tension | component | component |
| | (water) | methane) | (mJ/m²) | (mJ/m²) | (mJ/m²) |
| CIP-FID | ~83 | ~25 | 48.12 | 46.15 | 1.97 |
| CIP-PID | ~65 | ~21 | 55.57 | 44.17 | 8.17 |
| CIP-TEOS | ~52 | ~16 | 61.98 | 47.48 | 14.49 |
| CIP-APTES | ~25 | ~15 | 75.98 | 49.08 | 26.90 |
| PDMS | ~27.1 | ~0 | 76.07 | 50.8 | 25.27 |

Based on the identifying result of the ΔG values of the CIPs with different surfaces, the ΔGs of the CIP with SiO₂ on the surface (CIP-FID) and the CIP without SiO₂ on the surface (CIP-PID) are −34.9 and −50.6 mN/m, respectively. The PDMS in the liquid state before the curing exhibited a surface energy value of about 25.27 mN/m and a relatively high polarity of 33.22%. The CIP-PID has a larger polarity component than that of CIP-FID, so the ΔG value of the CIP-PID is smaller than that of the CIP-FID. Furthermore, the ΔG values of CIPs treated with TEOS and APTES, respectively, were −60.42 and −75.94, respectively, which were smaller than that of the CIP-PID. The negative ΔG value indicates the presence of a thermodynamically spontaneous wetting system.

Therefore, all CIPs are expected to be uniformly dispersed in PDMS. Overall, all CIPs as tested were homogeneously dispersed throughout the composite. This may be attributed to the negative ΔG of all CIPs. However, the CIP-FID exhibits a larger amount of inter-particle agglomeration than CIP-PID does. Furthermore, the CIP treated with each of TEOS and APTES exhibits a smaller amount of inter-particle agglomeration that CIP-PID does. This trend is consistent with the result of the ΔG where the CIP-FID has the largest ΔG. Therefore, it was identified that the partial bonding of CIP and PDMS at the interface therebetween improved the dispersibility of the CIPs in the PDMS.

### Experimental Example 3: Mechanical Properties of CIP-PID/PDMS and CIP-PID/PDMS

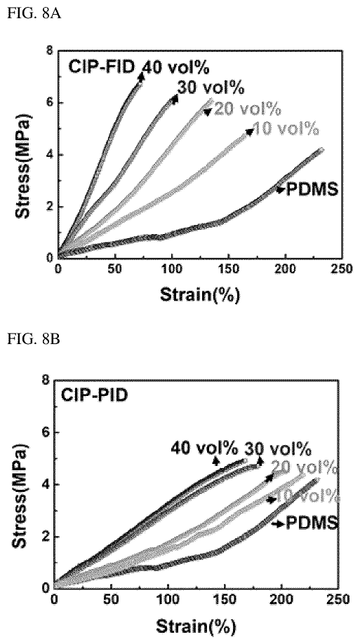

FIG. 7A is a SEM photograph of the composite after applying tensile stress thereto when the SiO₂ oxide film is removed from CIP and FIG. 7B is a SEM photograph of the composite after applying tensile stress thereto when the SiO₂ oxide film is not removed from CIP. FIG. 8A shows the tensile test results based on CIP content when the SiO₂ oxide film is not removed from CIP, FIG. 8B shows the tensile test results based on CIP content when the SiO₂ oxide film is removed therefrom, and FIG. 8C shows the tensile test results based on CIP content in case of CIP composite using various polymer matrices.

Referring to FIG. 7A-7B and FIG. 8A-8B, the mechanical properties of each of CIP-PID/PDMS and CIP-FID/PDMS under tensile strain may be identified. Overall, the CIP-PID/PDMS material shows a much higher failure strain value than the CIP-FID/PDMS material at the same filler content, which is close to the result of the pure PDMS. The CIP-PID/PDMS exhibited a failure strain of FIG. 168.5% using 40 vol % filler, which is twice that of CIP-FID/PDMS. The failure strain of CIP-FID/PDMS may be improved to 165.4% by reducing the filler content to 10 vol %. However, the EM noise suppression performance may be reduced due to the low filler content. The tensile strength of the composite materials exhibited a similar trend to the failure strain, and the tensile strength of CIP-FID/PDMS increased to a greater extent than that of CIP-PID/PDMS as the filler content increased. However, the tensile strength of CIP-PID/PDMS is greater than that of pure PDMS itself which is 4.16 MPa, and is sufficient for various wearable electronic applications.

The science behind the improved stretchability of CIP-PID/PDMS may be explained based on the ability of the partial interface bonding to cope with the strain induced by increasing the free surface of the PDMS matrix. In the CIP-FID/PDMS, due to full interface bonding between CIP and PDMS matrix, cracking occurred at the particle-matrix interface. In this condition, the applied strain is confined to the interface and thus, failure occurs due to cracks propagating along the interface.

In the CIP-FID/PDMS, the occurrence of cracks became more pronounced as the CIP content increased in the full interface bonding state. However, in the CIP-PID/PDMS, the CIP particles were partially bonded to the PDMS matrix to secure the free surface of the PDMS matrix at the particle interface. The weak and incomplete bonding of the CIP-PID at the interface allowed the PDMS matrix to stretch under tensile strain without crack initiation due to stress localization.

The free surface of CIP-PID/PDMS increases. This alleviates the applied strain without severe strain localization at the powder-matrix interface. Therefore, the stretchability of the composite was improved. However, the improved dispersion state of the CIP-PID in the PDMS compared to that of the CIP-FID in the PDMS cannot be the cause of the increased stretchability. This is because the mechanical properties of the composite of PDMS/CIP treated with each of APTES and TEOS which exhibited greater dispersion in the PDMS, behave similarly to those of the composite of PDMS/CIP-FID. A fully bonded interface between PDMS and CIP-FID may occur as well as the fully bonded interface between PDMS and CIP treated with each of APTES and TEOS may occur. This allowed the partial interface bonding (PID) to be identified as a major contributor to the improvement of stretchability of CIP-PID/PDMS.

### Experimental Example 4: FEM Simulation of the Mechanical Behavior of PDMS Composite Based on Each of CIP-PID and CIP-FID

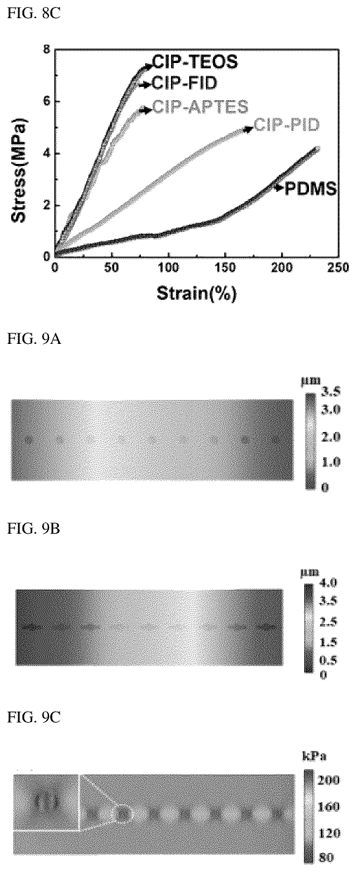

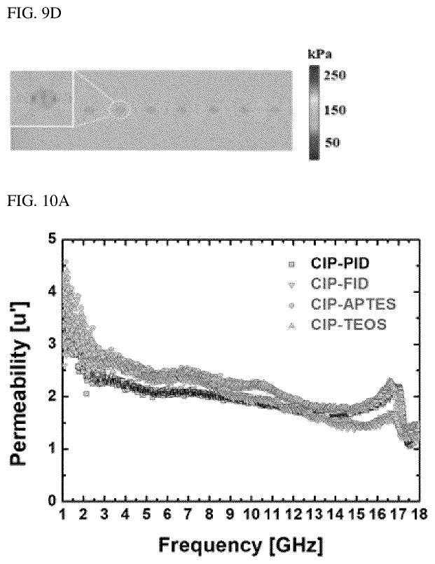

FIG. 9A to 9D show the numerically calculated displacement at a tensile load of 100 kPa of each of FIG. 9A CIP-FID based PDMS composite and FIG. 9B CIP-PID based PDMS composite, and the stress component calculated below 100 kPa of each of FIG. 9C CIP-FID based PDMS composite and FIG. 9D CIP-PID based PDMS composite.

Referring to FIG. 9A-9D, a CIP-FID based PDMS composite model and a CIP-PID based PDMS composite model are subjected to numerical simulation. The CIP-FID based PDMS composite and the CIP-PID based PDMS composite have own similar topology. Thus, only the portion thereof was expanded in the simulation. In the simulation, modeling was carried out in a scheme in which the other end thereof was fixed and the other end thereof was pulled. In the simulation, a tensile load of 100 KPa was applied to one end of the composite while the other end remained fixed. The CIP-FID based PDMS composite had a stretchability of 3.6%, while the CIP-PID based PDMS composite had a stretchability of 4.40%.

Holes or voids in the CIP/PDMS interface of the CIP-PID/PDMS composite are stretched along the tensile direction, thereby improving the stretchability. In the case of the CIP-FID/PDMS composite, the applied stress was concentrated at the interface between CIP and PDMS, and its magnitude was observed to be approximately 2.2 times the stress applied to the surrounding PDMS matrix.

However, the CIP-PID/PDMS composite exhibited uniform stress distribution throughout the CIP-PID/PDMS composite. In this case, the magnitude of the stress applied to the interface of the CIP-PID/PDMS composite was much smaller than that applied to the interface of the CIP-FID/PDMS composite. As the number of the holes at the interface of the CIP-PID/PDMS composite increases, the stress may be reduced. Thus, the stress concentration is smaller at the interface of the CIP-PID/PDMS composite than that at the interface of the CIP-FID/PDMS composite. These results are consistent with the experimental observation that the stretchability of the CIP-PID/PDMS composite is improved due to the increase in the free space of the PDMS matrix formed at the partially bonded interface of the CIP-PID/PDMS composite.

### Experimental Example 5: EM Noise Suppression Performance of Each of CIP-PID/PDMS Composite and CIP-FID/PDMS Composite

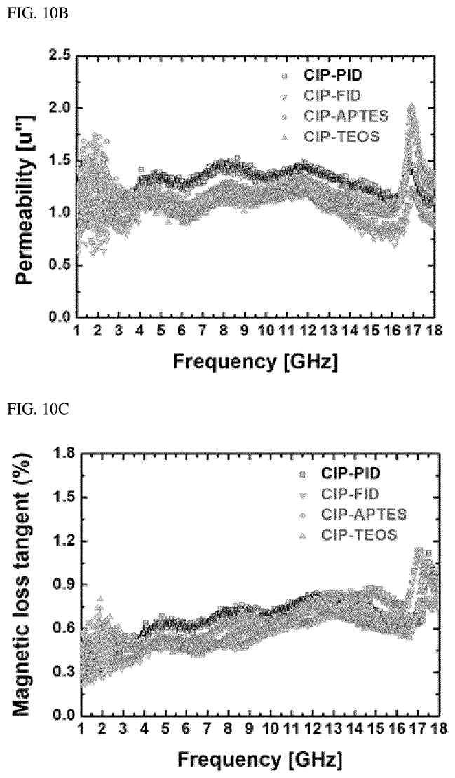

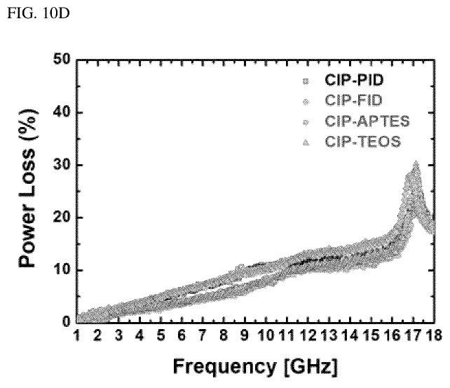

FIG. 10A and 10B show a real part and an imaginary part of the permeability of CIP/PDMS composite in the frequency range of 1 to 18 GHZ, and FIG. 10C and 10D show magnetic loss tangent and power loss of the CIP/PDMS composite in the frequency range of 1 to 18 GHz.

Referring to FIG. 10A-10B, the noise reduction effect depending on whether or not the oxide film is removed from CIP may be identified. In FIG. 10, CIP-PID refers to a CIP-PID/PDMS composite in which the oxide film is removed from CIP. CIP-FID refers to a CIP-FID/PDMS composite in which the oxide film is not removed from CIP. CIP-APTES refers to the CIP/PDMS composite in which the oxide film is removed from CIP and then APTES is coated thereon. CIP-TEOS refers to the CIP/PDMS composite in which the oxide film is removed from CIP and then TEOS is coated thereon. In general, eddy currents generated at the interface between neighboring CIPs deteriorate the EM noise suppression performance of the composite material. The function of the SiO₂ layer prevents these eddy currents. Therefore, removing the oxide film from the CIP surface deteriorates noise suppression performance. To identify the effect of the SiO₂ layer on the CIP surface on the EM noise suppression performance of the CIP/PDMS composite, the magnetic EM noise absorption characteristics of the PDMS/CIP composite fabricated using each of the CIP-PID and the CIP-FID were measured.

Electromagnetic wave absorption performance is mainly affected by the complex permittivity and the permeability and is expressed as follows.

(ε*=ε′=jε″)

μ*=μ′−jμ″ (Ramirez et al.)

In this regard, the real part (ε′, μ′) and the imaginary part (ε″, μ″) represent the storage capacity and loss of electric and magnetic energy, respectively. Because PDMS is an electrical insulator, the CIP/PDMS composite has significantly lower complex permittivity and dielectric loss tangent than permeability and magnetic loss tangent.

$$tan {δ}_{ε} = \frac{{ε}^{″}}{{ε}^{′}} \\ tan {δ}_{μ} = \frac{{μ}^{″}}{{μ}^{′}}$$

Therefore, the EM absorption efficiency of the CIP/PDMS composite material is mainly determined by the self-absorption characteristics of CIP. FIG. 10 shows results of the real part μ′ and the imaginary part μ″ of the complex permeability of the PDMS composite using the CIP surface-treated so as to have different surfaces as measured as a function of EM wave frequency in the 1 to 18 GHz range.

The CIP/PDMS composite absorbs a larger amount of EM waves with the increasing filler content due to the enhanced magnetic properties of the composite achieved by increasing the CIP content with high magnetization. Therefore, the maximum CIP content in the composite was fixed at approximately 40 vol % for EM absorption tests. The CIP-PID/PDMS composite exhibited similar real and imaginary values over the entire frequency range to those of the CIP-FID/PDMS composite.

The PDMS composite using CIP coated with each of APTES and TEOS exhibited a similar trend to the CIP-PID or CIP-FID/PDMS composite in terms of permeability change as a function of EM wave frequency. This may be due to similar values of the real and imaginary parts of the permeability in the frequency range. EM wave absorption converted into heat energy is expressed as power loss as follows.

power loss∝t\sqrt{fμᵣσ},

In this regard, t, f, μᵣ and σ are sample thickness, frequency, relative permeability and conductivity, respectively. The power loss levels in the test frequency range of all PDMS composites with different CIP contents were similar to each other. These results indicate that changes in the surface of CIP do not have a significant effect on EM noise suppression performance. Due to the excellent wettability of the CIP filler with the PDMS matrix, an insulating PDMS layer that encapsulates the surface may be formed and thus may replace the SiO₂ layer.

Therefore, in the CIP/PDMS composite, the CIP without the SiO₂ layer contributed to EM noise suppression performance at a similar level. The tensile test results show that the proposed CIP-PDMS composite could be deformed without sacrificing the EM noise suppression performance despite surface deformation. The results of this study may overcome the trade-off between the stretchability and the EM noise suppression performance, which is governed by the filler content as typically observed in polymer matrix composites.

The purpose of the present disclosure is to overcome the trade-off between stretchability and EM noise suppression as commonly observed in the polymer matrix composite by modifying the surface of the CIP so as to have incomplete partial interface bonding with the PDMS. Typically, CIP is covered with an oxide layer (SiO₂) to prevent eddy currents. Thus, a strong FID of CIP with PDMS via covalent bonds in the oxide layer may be achieved. Accordingly, the PID of CIP with the PDMS matrix is achieved by removing the oxide layer from CIP. This lowers the wettability of the CIP with the PDMS and improves the dispersion of CIPs in PDMS. Based on a result of the tensile test of the PDMS composite using each of CIP-PID and CIP-FID, the surface modification of the CIP may achieve the highly stretchable composite of the stretchability of approximately 168% even at a high filler content of approximately 40 vol %, whereas the non-surface-treated CIP may achieve the composite of the stretchability of approximately 71% at a high filler content of approximately 40 vol %. Based on the microstructural analysis and FEM simulation, the EM noise suppression performance of the CIP/PDMS composite exhibits no significant change based on whether the surface modification is applied to the CIP. The EM noise suppressor composite material prepared using the CIP-PID achieves the high stretchability and excellent EM absorption properties. A combination of mass-producible and inexpensive CIPs with a simple mixing process for composite preparing would be promising for the highly stretchable composites for EM noise suppressors, especially in industrial applications.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A method for preparing a highly stretchable CIP/PDMS composite for a highly stretchable EM noise suppressor, the method comprising:
a first step of adding and mixing CIPs (Carbonyl Iron Powders) to and with a PDMS (Polydimethylsiloxane) solution to produce a first mixed solution;
a second step of adding and mixing a curing agent to and with the first mixed solution to produce a second mixed solution; and
a third step of transferring the second mixed solution into a mold and then curing the second mixed solution in the mold.

2. The method of claim 1, wherein each of the CIPs is free of a surface oxide film.

3. The method of claim 2, wherein the surface oxide film is made of silicon oxide (SiO₂).

4. The method of claim 2, wherein the surface oxide film has been removed from each of the CIPs by sequentially washing the CIPs using 0.5 M hydrochloric acid (HCl), distilled water, ethanol, and acetone.

5. The method of claim 2, wherein the CIPs from which the surface oxide film has been removed is added to the first mixed solution at a content of 40 vol % or smaller based on a total volume of the first mixed solution.

6. The method of claim 2, wherein in a mixture of the CIPs and the PDMS, a free space is defined around the CIP.

7. The method of claim 1, wherein the mixing of each of the first step and the second step is carried out using a revolving and rotating mixer.

8. The method of claim 1, wherein the curing includes thermal curing, wherein a thermal curing temperature is in a range of 80 to 120° C.

9. A highly stretchable CIP/PDMS composite prepared by the method of claim 1.

10. The highly stretchable CIP/PDMS composite of claim 9, wherein each of the CIPs is free of a surface oxide film.

11. The highly stretchable CIP/PDMS composite of claim 10, wherein the surface oxide film is made of silicon oxide (SiO₂).

12. The highly stretchable CIP/PDMS composite of claim 9, wherein the CIP/PDMS composite has a stretchability of about 165% or greater.

13. The highly stretchable CIP/PDMS composite of claim 9, wherein the CIP/PDMS composite removes electromagnetic (EM) noise.

14. A highly stretchable EM noise suppressor including the highly stretchable CIP/PDMS composite of claim 9.
